(19) United States
(12) Patent Application Publication
(10) Pub. No.: US 2017/0345862 A1
(43) Pub. Date: Nov. 30, 2017

(54) SEMICONDUCTOR PACKAGE WITH INTERPOSER

(71) Applicant: SEMICONDUCTOR COMPONENTS INDUSTRIES, LLC, Phoenix, AZ (US)

(72) Inventors: Larry KINSMAN, Boise, ID (US); Yu-Te HSIEH, Taoyuan City (TW); Chi-Yao KUO, Taipei (TW)

(73) Assignee: SEMICONDUCTOR COMPONENTS INDUSTRIES, LLC, Phoenix, AZ (US)

(21) Appl. No.: 15/166,007

(22) Filed: May 26, 2016

(51) Int. Cl. H01L 27/146

(52) U.S. Cl. CPC H01L 27/14634; H01L 27/1469; H01L 27/14618; H01L 27/14636

(57) ABSTRACT

Implementations of semiconductor packages may include: a first semiconductor die coupled to a first side of a substrate having one or more internal traces. One or more connectors coupled to the first semiconductor die and the first side of the substrate. A glass lid coupled to the first side of the substrate over the first semiconductor die. A mold compound that encapsulates at least a portion of the substrate. A second semiconductor die coupled to a second side of the substrate opposing the first side. The second semiconductor die is electrically coupled with the first semiconductor die through the one or more traces of the substrate.

### BACKGROUND

### 1. Technical Field

Aspects of this document relate generally to semiconductor packages having a trace between two or more dice. More specific implementations involve chip on board packages with image sensors.

### 2. Background

Various systems and devices have been devised to allow semiconductor chips to connect with motherboards and other mounting technology. Conventionally, to connect a sensor chip with a processor chip the two packages are coupled separately to a printed circuit board and connected through a trace on the board.

### SUMMARY

Implementations of semiconductor packages may include: a first semiconductor die coupled to a first side of a substrate having one or more internal traces. One or more connectors may be coupled to the first semiconductor die and the first side of the substrate. A glass lid coupled to the first side of the substrate over the first semiconductor die. A mold compound that encapsulates at least a portion of the substrate may be included. A second semiconductor die may be coupled to a second side of the substrate opposing the first side. The second semiconductor die may be electrically coupled with the first semiconductor die through the one or more traces of the substrate.

Implementations of semiconductor packages may include one, all, or any of the following:

At least one of a ball grid array, a land grid array or any combination thereof may be coupled to the second side of the substrate.

The one or more connectors may be wire bonds.

The substrate may be coupled to a motherboard using wire bonds.

The second semiconductor die may be coupled to the first semiconductor die through a pin out connector.

The substrate may be selected from the group consisting of a ceramic, an organic or any combination thereof.

Implementations of semiconductor packages may include: a first imaging chip coupled to a first side of an interposer comprising one or more internal traces. One or more connectors may be coupled to the first imaging chip and the first side of the interposer. A glass lid may be coupled to the first side of the interposer over the first imaging chip. A mold compound may encapsulate at least a portion of the substrate. A ball grid array may be coupled to a second side of the interposer. A second imaging chip may be coupled to the second side of the interposer. The second imaging chip may be electrically coupled to the first imaging chip through one or more traces of the interposer.

Implementations of semiconductor packages may include one, all, or any of the following:

The one or more connectors may be wire bonds.

The interposer may be coupled to a motherboard using wire bonds.

The second semiconductor die may be coupled to the first semiconductor die through a pin out connection.

The substrate may be selected from the group consisting of a ceramic, an organic or any combination thereof.

Implementations of semiconductor packages may be manufactured using implementations of a method of making a semiconductor package. The method may include providing a substrate having one or more traces therein. The method may also include mechanically and electrically coupling a first semiconductor die to the substrate with one or more connectors. A glass lid may be coupled to a first side of the substrate over the first semiconductor die. At least a portion of the substrate may be encapsulated. A second semiconductor die may be mechanically and electrically coupled to a second side of the substrate opposing the first side. The first semiconductor die may be electrically coupled to the second semiconductor die through one or more traces.

Implementations of a method of making a semiconductor package may include one, all or any of the following:

A plurality of balls may be coupled to the substrate to form a ball grid array.

The first semiconductor die may be an imaging chip.

The second semiconductor die may be selected from the group consisting of signal processing random access memory (RAM), flash memory, an image signal processor, or any combination thereof.

The second semiconductor die may have a redistribution layer, an under bump metallization pad, one or more gold bumps, one or more copper pillar bumps, one or more solder bumps, or any combination thereof.

The second die may be coupled to the substrate using non-conductive paste.

The second semiconductor die may be coupled to the substrate using solder and an underfill material.

The second semiconductor die may be coupled to the substrate using ultrasonic bonding, thermal compression, or surface mount reflow.

An underfill material may be added in a space between the second semiconductor die and the substrate.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a view of a conventional implementation of two die connected by a trace on a printed circuit board;

FIG. 2 is a front view of an implementation of a semiconductor package with an interposer;

FIG. 3A is a front view of another implementation of a semiconductor package with an interposer;

FIG. 3B is a perspective view of the top of another implementation of a semiconductor package with an interposer from FIG. 3A;

FIG. 3C is a perspective view of the bottom of an implementation of a semiconductor package with an interposer from FIG. 3A;

FIG. 4A is a top view of an additional implementation of a semiconductor package with an interposer;

FIG. 4B is a bottom view of an additional implementation of a semiconductor package with an interposer from FIG. 4A;

FIG. 4C is a side view of an additional implementation of a semiconductor package with an interposer from FIG. 4A.

### DESCRIPTION

This disclosure, its aspects and implementations, are not limited to the specific components, assembly procedures or method elements disclosed herein. Many additional components, assembly procedures and/or method elements known in the art consistent with the intended semiconductor package will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

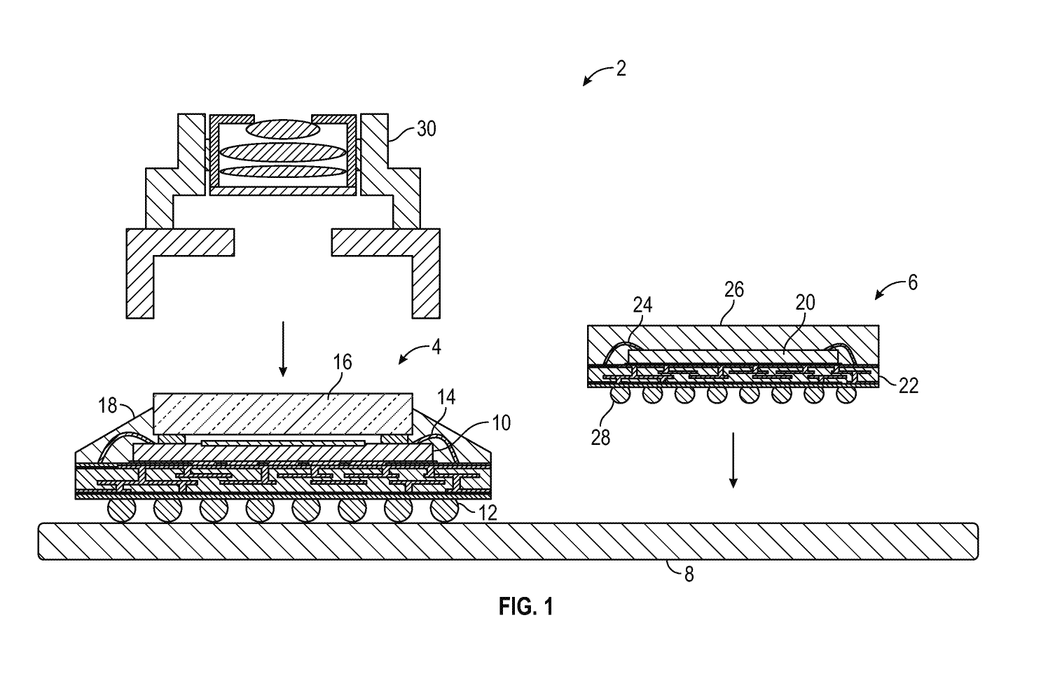

Referring to FIG. 1, a conventional implementation 2 of a complementary metal oxide semiconductor (CMOS) imaging sensor (CIS) 4 connected to an image signal processor (ISP) 6 by a long trace on a printer circuit board (PCB) 8 is illustrated. The single CIS die 10 is packaged in a chip-on-board (COB) process with a ball grid array (BGA) 12. The CIS die 10, wire bonds 14, and glass lid 16 are encapsulated in a liquid encapsulant (LE) 18. The ISP die 20 is also bonded to a substrate 22 by wire bonds 24. The ISP die 20 and substrate 22 are then encapsulated in a liquid encapsulant 26. The ball grid array 28 is added to the substrate 22 of the ISP package 6 before the ISP package 6 is mounted to the PCB 8. A lens module 30 may be coupled to the CIS package 4. This conventional implementation requires a long trace to connect the CSP 4 to the ISP 6 package which may lead to poor signal integrity and a large module size.

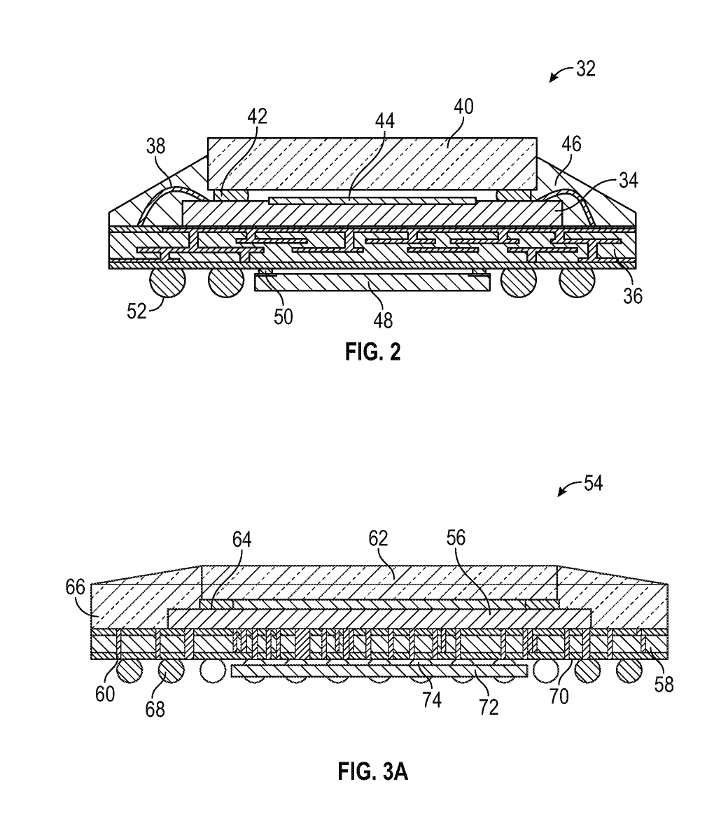

Referring to FIG. 2, an implementation of a semiconductor package with an interposer 32 is illustrated. In this implementation, a first semiconductor die 34 is coupled to a first side of a substrate/interposer 36 by an adhesive and by connectors 38. The substrate/interposer 36 may be a multilevel substrate with one or more internal traces through the levels as illustrated. The connectors 38 may include a wire made out of any electrically conductive material (wirebonds, etc.). A glass lid 40 is coupled to the first semiconductor die 34 by an adhesive 42 to protect the first semiconductor die 34. The glass lid 40 is positioned over the sensing area 44 of the first semiconductor die 34 and the adhesive 42 is coupled to the first semiconductor die 34 on/at the non-sensing area. The adhesive may be epoxy, resin, solder or any other bonding system capable of coupling the glass to the die. A mold compound/liquid encapsulant (LE) 46 (which may be a liquid epoxy in various implementations) covers at least a portion of the substrate/interposer 36. The mold compound/LE 46 protects the connectors 38 from mechanical damage and protects the area where the glass lid 40 and first semiconductor die 34 are coupled together from moisture. A second semiconductor die 48 is coupled to the second side of the substrate/interposer 36 opposing the first side. The second semiconductor die 48 may be coupled to the substrate/interposer through solder 50. An underfill material may be added in the space between the substrate/interposer 36 and the second semiconductor die 48. The second semiconductor die 48 is electrically coupled with the first semiconductor die 34 through the one or more traces of the substrate/interposer 36. The substrate 36 acts as an interposer between the first semiconductor die 34 and the second semiconductor die 48. A ball grid array 52 is coupled to the second side of the substrate 36. In other implementations, however, a land grid array, a pin grid array, or any combination of array structures may also be used.

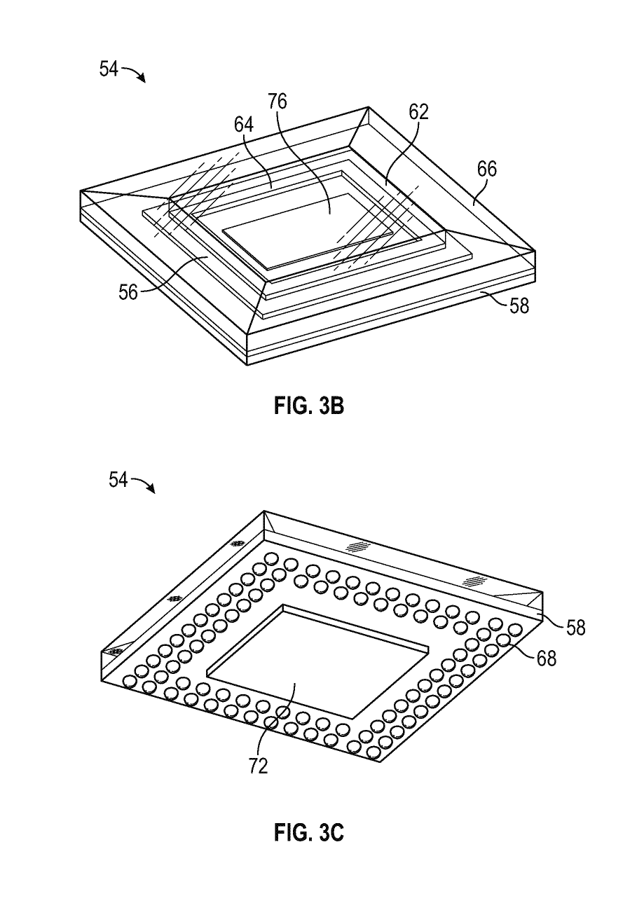

Referring to FIG. 3A, a side view of another implementation of a semiconductor package with an interposer 54 is illustrated. A first semiconductor die 56 is electrically coupled to a first side of a substrate 58 with through silicon vias 60. A glass lid 62 is coupled to the first semiconductor die 56 by an adhesive 64. The substrate may have a redistribution layer 70. A ball grid array 68 may be coupled to the second side of the substrate 58, though other array types disclosed herein could be used. The substrate 58 may also be coupled to a mother board or printed circuit board using wire bonds. The first semiconductor die 56 and the second semiconductor die 72 are likewise be connected to the motherboard through the substrate. A second semiconductor die 72 is coupled to the second side of the substrate 58 through solder and an underfill material 74. The second semiconductor die 72 may also be coupled to the substrate 58 through non-conductive paste or ultrasonic bonding and one or more gold bumps. In various implementations, copper pillar bumps, solder bumps, gold bumps, or any combination thereof may be used. In these various implementations, the coupling of the die 72 to the substrate 58 may take place using thermal compression, surface mount (SMT) reflow, and any other method of coupling the material of the bumps to the substrate. The second semiconductor die 72 may be electrically coupled to the first semiconductor die 56 through a pin out connector.

Referring to FIG. 3B, a top view of another implementation of a semiconductor package with an interposer 54 from FIG. 3A is illustrated. In this view, the sensing area 76 on the first semiconductor die 58 is illustrated through the glass lid 62. The adhesive 64 coupling the glass lid 62 to the first semiconductor die 58 is illustrated as a border around the edge of the first semiconductor die 56. The molding compound 66 extends to the edge of the substrate/interposer 58. Referring to FIG. 3C, a bottom view of another implementation of a semiconductor package with an interposer 54 from FIG. 3A is illustrated. In this view, the second semiconductor die 72 coupled to the second side of the substrate 58 is shown. The ball grid array 68 is shown to surround the second semiconductor die 72 on the second side of the substrate 58. The balls of the ball grid array 68 extend past the plane formed by the bottom of the second semiconductor die 72.

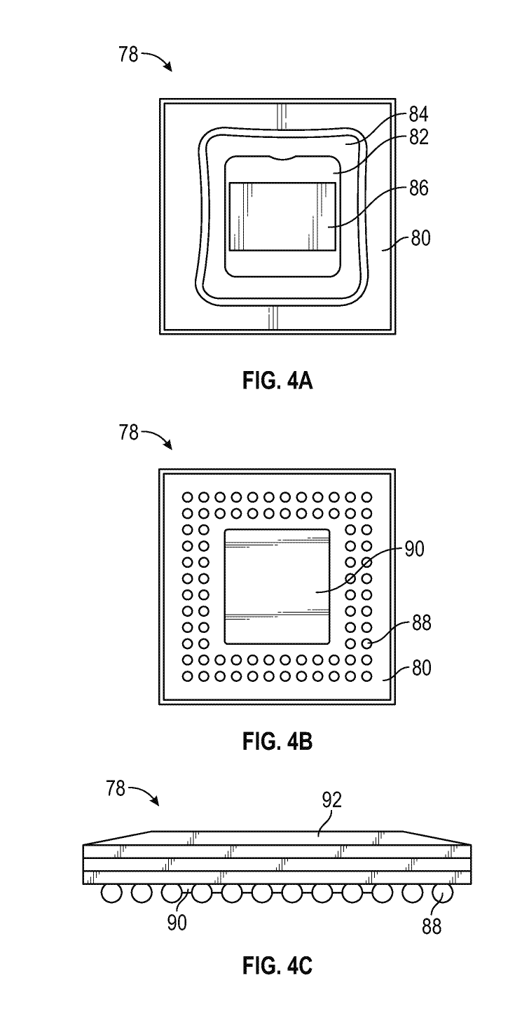

Referring to FIG. 4A, a top view of an additional implementation of a semiconductor package with an interposer 78 is illustrated. The first semiconductor die 82 is coupled to the substrate 80. The glass lid 84 is coupled to the first semiconductor die 82 over the sensing area 86 of the first semiconductor die 82. By non-limiting example, the sensing area 86 of the first semiconductor die 82 may be a pixel array or the active area of a light emitting diode (LED) die. In such LED implementations, the sensing area becomes an active area that actively emits light.

Referring to FIG. 4B, a bottom view of the additional implementation of a semiconductor die with interposer 78 from FIG. 4A is illustrated. In this view, a ball grid array 88 is coupled to the second side of the substrate 80. The second semiconductor die 90 is also coupled to the second side of the substrate 80. Referring to FIG. 4C, a side view of the additional implementation of a semiconductor die with interposer 78 from FIG. 4A is illustrated. In this view, the mold compound 92, ball grid array 88 and second semiconductor die 90 are visible.

Semiconductor packages like those described herein may be manufactured using implementations of methods for manufacturing semiconductor packages. Implementations of the method may include, providing a substrate 36/58/80 having one or more traces. A first semiconductor die 34/56/76 may be coupled to the substrate with one or more connectors. A glass lid 40/62/84 may be coupled to a first side of the substrate over the first semiconductor die 34/56/76. At least a portion of the substrate 36/58/80 may be encapsulated. A second semiconductor die 48/72/90 may be mechanically and electrically coupled to a second side of the substrate 36/58/80 opposing the first side. The second semiconductor die 48/72/90 may be selected from the group consisting of signal processing random access memory (RAM), flash memory, an image signal processor, or any combination thereof. The second semiconductor die 48/72/90 may further comprise a redistribution layer, an under bump metallization pad, and one or more gold bumps (though other metals could be used in various implementations). The first semiconductor die 34/56/76 may be coupled to the second semiconductor die 48/72/90 through one or more traces.

In places where the description above refers to particular implementations of a semiconductor package and implementing components, sub-components, methods and sub-methods, it should be readily apparent that a number of modifications may be made without departing from the spirit thereof and that these implementations, implementing components, sub-components, methods and sub-methods may be applied to other semiconductor packages.

1. A semiconductor package comprising:
a first semiconductor die coupled to a first side of a substrate comprising one or more internal traces;
one or more connectors coupled to the first semiconductor die and the first side of the substrate;
a glass lid coupled to the first side of the substrate over the first semiconductor die;
a mold compound that encapsulates at least a portion of the substrate; and
a second semiconductor die coupled to a second side of the substrate opposing the first side;
wherein the second semiconductor die is electrically coupled with the first semiconductor die through the one or more traces of the substrate.

2. The semiconductor package of claim 1, further comprising at least one of a ball grid array, a land grid array, a pin grid array and any combination thereof coupled to the second side of the substrate.

3. The semiconductor package of claim 1, wherein the one or more connectors are wire bonds.

4. The semiconductor package of claim 1, wherein the substrate is coupled to a motherboard using wire bonds.

5. (canceled)

6. The semiconductor package of claim 1, wherein the substrate is selected from the group consisting of a ceramic, an organic and any combination thereof.

7. A semiconductor package comprising:
a first imaging chip coupled to a first side of an interposer comprising one or more internal traces;
one or more connectors coupled to the first imaging chip and the first side of the interposer;
a glass lid coupled to the first side of the interposer over the first imaging chip;
a mold compound that encapsulates at least a portion of the substrate;
a ball grid array coupled to a second side of the interposer; and
a second imaging chip coupled to the second side of the interposer;
wherein the second imaging chip is electrically coupled to the first imaging chip through the one or more traces of the interposer.

8. The semiconductor package of claim 7, wherein the one or more connectors are wire bonds.

9. The semiconductor package of claim 7, wherein the interposer is coupled to a motherboard using wire bonds.

10. (canceled)

11. The semiconductor package of claim 7, wherein the substrate is selected from the group consisting of a ceramic, an organic and any combination thereof.

12-20. (canceled)
